(19) United States
(12) Patent Application Publication
(10) Pub. No.: US 2010/0308436 A1
(43) Pub. Date: Dec. 9, 2010

(54) SEMICONDUCTOR DEVICE AND MANUFACTURING METHOD THEREOF

(75) Inventor: Kenji NANJO, Kyoto (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/792,119

(22) Filed: Jun. 2, 2010

(30) Foreign Application Priority Data
Jun. 8, 2009 (JP) 2009-137760

(51) Int. Cl. H01L 29/8605; H01L 21/02

(52) U.S. Cl. 257/536; 438/382; 257/E29.326; 257/E21.004

(57) ABSTRACT

The present invention provides a semiconductor device including a resistor which achieves reduction of a chip size and variations in resistance value, and a manufacturing method thereof. The semiconductor device includes: a resistor which is linearly formed above the silicon substrate, and made mainly of silicon; contact forming areas each of which (i) is formed in contact with one end of the resistor, and (ii) has a surface made of metal silicide; and contact plugs each of which electrically connects an associated one of the contact forming areas to a metal wire formed on the interlayer insulating film. An in-plane pattern of each of the contact forming areas is bent at least twice in a planar direction with respect to a linear direction of the resistor, so that a part of the contact forming area is formed in parallel with the resistor.

### BACKGROUND OF THE INVENTION

(1) Field of the Invention

The present invention relates to semiconductor devices and manufacturing methods thereof, the semiconductor devices which include a resistor used for an analogue circuit, and in particular, to a poly-silicon resistor used as a resistor which requires low parasitic capacitance and high resistive accuracy.

(2) Description of the Related Art

Resistors are used at various places on an analogue circuit. When used alone, a resistor is a factor to determine circuit characteristics, such as a CR product of an integrating circuit and a differentiating circuit and a conversion ratio of a current-voltage converting circuit. Thus, variation in resistance value of a stand-alone resistor is one of important factors in designing an analogue circuit. In addition, when resistors are used in a pair, a difference and a resistance ratio between the resistance values of the resistors are factors to determine circuit characteristics, such as a difference gain of a differential amplifier circuit. Hence, the variation observed between the resistance values of the paired resistors is one of important factors in designing an analogue circuit.

A well-known fact sees that, in general, a larger resistor size can further reduce the variations in resistance value. In order to realize predetermined circuit characteristics, conventional resistors have been designed to have (i) either the size of the resistor gained or the resistor variable, and (ii) a matching circuit provided.

Described below is a typical manufacturing method of a poly-silicon resistor. First, a poly-silicon layer is formed on a silicon substrate by the low pressure chemical vapor deposition (CVD). Next, a resist pattern is formed on the poly-silicon layer using lithography. Then, the resist-patterned poly-silicon layer goes through the reactive ion etching (RIE) in order to get unnecessary parts other than a resistor removed, which forms a poly-silicon resistor pattern.

The above etching on the poly-silicon layer causes the micro-loading effect. The effect (i) narrows the width of the poly-silicon resistor pattern where the pattern is densely formed, and, on the contrary, (ii) greatly varies the width of the pattern where the pattern is sparsely formed. Accordingly, the varying resistor size causes variations in resistance value.

FIG. 9 is a plan view of densely and sparsely arranged conventional poly-silicon resistors. According to poly-silicon resistors R1 and R2 in FIG. 9, the resistor R1 is formed with the patterns densely formed. Concurrently, another resistor, the resistor R2, is provided with the pattern sparsely formed. In this case, the micro-loading effect reduces the width w1 of each resistor R1, and, on the contrary, increases the width w2 of the resistor R2. This effect causes a problem of varying the resistance value.

In order to solve the above problem, Patent Reference 1 (Japanese Unexamined Patent Application Publication No. 04-064217) has been introduced. Patent Reference 1 is characterized in having (i) few variations in resistance value, and (ii) dummy patterns arranged around a resistor which requires a particularly low mismatch. Here, the dummy patterns are formed of the poly-silicon layer of which the resistor is also made.

FIG. 10A is a plan view of a poly-silicon resistor in accordance with a publicly-known example described in Patent Reference 1. FIG. 10B is a cross-sectional view of the poly-silicon resistor in accordance with a publicly-known example described in Patent Reference 1. The resistor R1 and the resistor R2 are poly-silicon resistors which require a low mismatch. Arranged both sides of each of the resistors R1 and R2 are respective dummy patterns D1 and D2. The distance “x1” between the resistor R1 and the dummy pattern D1 is equal to the distance “x2” between the resistor R2 and the dummy pattern D2. In addition, the distances “x1” and “x2” follow the minimum rule; that is, the distances should meet the shortest design-wise allowable distances between the R1 and the D1 and between the R2 and the D2. It is noted that formed on the resistors R1 and R2 are contact plugs C used for conducting with the resistors R1 and R2. This arrangement makes possible equalizing the local pattern arrangement density near the resistors R1 with that near the R2, using the dummy patterns D1 and D2, even though the pattern arrangement density around the resistors R1 and R2 is dense or sparse. Thus, the micro-loading effect is equally provided to each of the resistors R1 and R2. Accordingly, observed are few variations in width of a resistor, and reduced is the mismatch between the resistors R1 and R2.

FIGS. 11A and 11B are respectively a plan view and a cross-sectional view of a poly-silicon resistor in accordance with Embodiment 2 described in Patent Reference 1. Embodiments 1 and 2 illustrated in FIGS. 11A and 11B have dummy patterns G1 and G2 each provided to form a guard ring around the resistors R1 and R2, respectively. Here, the resistors R1 and R2 are made of poly-silicon. Following the above minimum rule, the distance between the resistor R1 and the dummy pattern G1; namely a clearance y1, and the distance between the resistor R2 and the dummy pattern G2; namely a clearance y2, have the same value (y1=y2). According to Embodiments 1 and 2, the pattern arrangement densities around the resistors R1 and R2 are equalized to reduce the mismatch between the resistors R1 and R2.

As described above, Patent Reference 1 involves providing dummy patterns around resistors to equalize local pattern arrangement densities near the patterns of the resistors. This equalized pattern densities can equally provide the micro-loading effect to each pattern, which reduces variations in resistance value due to variations in resistor size.

In order to achieve reduction of variations in resistance value, in general, a small parasitic resistance component is preferable. Here, the parasitic resistance component includes contact resistance and contact resistance generated between a contact and a resistor. Patent Reference 2 (Japanese Unexamined Patent Application Publication No. 2004-079893) discloses a technique to reduce contact resistance of a contact plug.

FIGS. 12A, 12B, and 12C show plan views of poly-silicon resistors in accordance with Embodiments 1, 2, and 3, respectively, of Patent Reference 2. Formed at both ends of resistors R3, R4, and R5 are silicided head portions S3, S4 and S5. The silicidation can reduce contributions of the resistance values of the head portions S3, S4, and S5, which reduces variations in resistance value of the resistors as a whole. Proposed head portions are (i) the head portion S4 having a head area enlarged in a longitudinal direction of the resistor R4 as illustrated in FIG. 12B; and (ii) the head portion S5 having a hammerhead head portion as illustrated in FIG. 12C. As described above, enlarged areas of the head portions make possible (i) having more contact plugs C; and (ii) further reducing the contact resistance between each contact plug C and an associated head portion. This possibly reduces variations in resistance value of the resistors as a whole.

### SUMMARY OF THE INVENTION

With the chip size reduced, resistors included in an analogue circuit are required to have, as the resistors in total, fewer variations in resistance value.

FIG. 13 is a graph illustrating resistance length dependency of a contact resistance contribution with respect to a resistance value of a resistor. The graph illustrated in FIG. 13 shows that when a resistor is large in size; that is the length resistance of the resistor is for example equal to 10 μm or greater, the parasitic resistance component is small in share of a resistance value of the total resistors. Thus, the contact resistance contribution is small. When the resistor is small in size; that is the length resistance of the resistor is for example 1 μm, the parasitic resistance component is great in share of a resistance value of the total resistors. Thus, the contact resistance contribution increases. Hence, a decrease in length resistance of a resistor leads to an increase in proportion of a parasitic resistance component in a resistance value of the total resistors.

Patent Reference 1 can reduce variations in resistance value due to variations, in processing accuracy of a resistor, caused by the micro-loading effect; however, Patent Reference 1 fails to takes into consideration parasitic resistance components, such as a resistance value of a contact plug, and contact resistance between a contact plug and a resistor. Hence, Patent Reference 2 cannot fully reduce variations occurring between resistance values of each of resistors included in an analogue circuit as the length resistance of the resistor becomes smaller.

FIG. 14 is a graph illustrating the number of contacts dependency of a contact resistance contribution with respect to a resistance value of a resistor. As the graph in FIG. 14 shows, the minimization of a semiconductor device increases the share of a resistance value of a contact plug in a resistance value of a resistor. This increase cannot be ignored.

In consideration of a resistance component of a head portion, Patent Reference 2 involves forming a contact area out of silicide, so that a resistance value of the head portion is lowered, and variations in resistance value of the resistor are reduced. In order to achieve a further reduction of the resistance of the head portion, however, Patent Reference 2 suggests enlarging an area of the head portion to increase the number of contacts, so that the contact resistance values are reduced in total, and variations in resistance value can be reduced. Accordingly, the head portion is enlarged either in a longitudinal direction or in a resistor-width direction of the resistor. This results in a greater resistor in total in resistor size.

FIG. 15A shows relationship between variations in resistance value of a resistor and the number of relative contacts. FIG. 15B shows relationship between a mismatch of a resistor and the number of relative contacts. The structure, subject to measurement, illustrated in the graphs shown in FIGS. 15 is the structure of the resistor R4 and the contact plug C shown in FIG. 12 (B). When the length of the resistor R4 is 1 μm, for example, doubling the number of the provided contact plugs C in a longitudinal direction of the resistor can reduce the absolute variation by 22% and the mismatch by 14%; however, the resistor area results in a 38-percent increase. Similarly, tripling the number of provided the contact plugs can reduce absolute variations by 36% and the number of mismatches by 25%; however, the resistor area results in a 75-percent increase.

As described above, a semiconductor device including a conventional resistor possibly reduces variations; however, such a semiconductor device results in a greater resistor size. Thus, achieving both of reducing a chip size and improving accuracy of an analogue circuit is highly improbable.

The present invention is conceived in view of the above problems and has as an object to provide a semiconductor device and a manufacturing method there of, the semiconductor device which achieves reduction in both of chip size and variation of a resistance value.

In order to achieve the above object, a semiconductor device according to an aspect of the present invention is included in an analogue circuit. The semiconductor device includes: a semiconductor substrate; a resistor which is linearly formed above the semiconductor substrate, and made mainly of silicon; contact forming areas each of which (i) is formed in contact with one end of the resistor, and (ii) has a surface made of metal silicide; an interlayer insulating film formed on the resistor and the contact forming areas; and contact plugs each of which penetrates the interlayer insulating film and electrically connects an associated one of the contact forming areas to a metal wire formed on the interlayer insulating film, wherein an in-plane pattern of each of the contact forming areas is bent at least twice in a planar direction with respect to a linear direction of the resistor, so that a part of the contact forming area is formed in parallel with the resistor.

The above structure allows the contact forming area, whose surface is metal-silicidized, to be disposed in parallel with the resistor, which makes possible equalizing local pattern densities near the patterns of the resistor. Thus, the structure can: equally provide the micro-loading effect to each pattern; and reduce variations in resistance value in order to reduce contact-plug-related resistance without enlarging a resistor size.

The resistor is preferably surrounded by the contact forming areas in a plane except a space lying between the contact forming areas.

The use of the aspect makes possible employing more efficient and accurate equalization of the micro-loading effect provided to each pattern.

The resistor may be surrounded in the plane by the contact forming areas and the resistor adjacent to the contact forming areas except a space lying between two from among the contact forming areas and the resistor adjacent to the resistor.

In the case where another resistor lies adjacent to the resistor, the resistor does not have to be surrounded only by the contact forming area; instead, a part of the other resistor lying adjacent to the resistor may be used as a structural element surrounding the resistor. The use of the aspect makes possible employing more efficient and accurate equalization of the micro-loading effect provided to each pattern.

The resistor, the contact forming areas and the contact plugs formed on the contact forming areas are preferably symmetrically arranged in the plane as viewed from center in the plane of the resistor.

The use of this aspect can uniform contact-plug-related resistance which occurs at the contact forming areas formed on both ends of the resistor, at the both ends of each resistor. Furthermore, a pattern shape of the resistor can be symmetrical. This can implement an analogue circuit having high accuracy, reflecting the designing.

A gap between the resistor and the part of the contact forming area is preferably a smallest allowable value for inter-pattern distance, the contact forming area being formed in parallel with the resistor.

The use of this aspect makes possible maximally equalizing the micro-loading effect provided to each pattern. In addition, the above aspect can minimize the distance between the resistor and the contact forming area, which can realize a smaller chip size.

Each of the contact forming areas preferably has a largest possible number of the contact plugs equally arranged.

The use of this aspect can maximally reduce contact-plug-related-resistance, without enlarging a resistor size, which occurs at the contact forming areas formed on both ends of the resistor.

It is noted that the present invention can be realized as a method for manufacturing a semiconductor device, the method which realizes characteristic units included in the semiconductor device as steps, as well as the semiconductor device including such characteristic units.

A semiconductor device according to an implementation of the present invention and a manufacturing method thereof makes possible simultaneously reducing variations in resistance value caused by (i) an increase in ratio of a contact resistance value, and (ii) the micro-loading effect without enlarging a resistor size even though a resistor included in an analogue circuit becomes smaller and the length resistance is reduced. Thus, the implementation can achieve both of reducing a chip size and improving accuracy of an analogue circuit.

### FURTHER INFORMATION ABOUT TECHNICAL BACKGROUND TO THIS APPLICATION

The disclosure of Japanese Patent Application No. 2009-137760 filed on Jun. 8, 2009 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1A is a plan view of a resistor and a contact forming area included in a semiconductor device in accordance with Embodiment 1 of the present invention, and FIG. 1B is a cross-sectional view of the semiconductor device in accordance with Embodiment 1 of the present invention;

FIG. 2 is a plan view, of a resistor and a contact forming area, illustrating a modification in accordance with Embodiment 1 of the present invention;

FIG. 3 is a cross-sectional flow sheet illustrating a manufacturing method of the semiconductor device in accordance with Embodiment 1 of the present invention;

FIG. 4A is a plan view of a resistor and a contact forming area both included in a semiconductor device in accordance with Embodiment 2 of the present invention, and FIG. 4B is a plan view of a resistor and a contact forming area both included in a semiconductor device in accordance with Embodiment 2 of the present invention;

FIG. 5A is a plan view of a resistor and a contact forming area both included in a semiconductor device in accordance with Embodiment 3 of the present invention, and FIG. 5B is a plan view of a resistor and a contact forming area both included in a semiconductor device in accordance with Embodiment 3 of the present invention;

FIG. 6 is a plan view of a resistor and a contact forming area both included in a semiconductor device in accordance with Embodiment 4 of the present invention;

FIG. 7 is a plan view of a resistor and a contact forming area both included in a semiconductor device in accordance with Embodiment 5 of the present invention;

FIG. 8 is a plan view of a resistor and a contact forming area both included in a semiconductor device in accordance with Embodiment 6 of the present invention;

FIG. 9 is a plan view of densely and sparsely arranged conventional poly-silicon resistors;

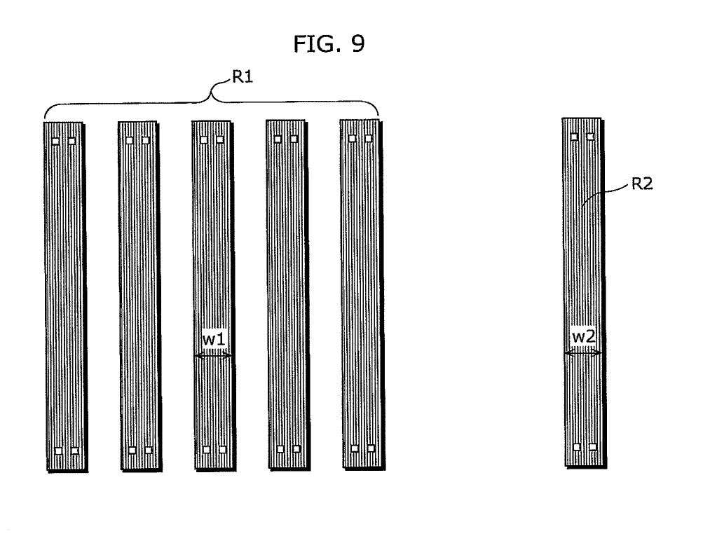

FIG. 10A is a plan view of the poly-silicon resistor in accordance with Embodiment 1 described in Patent Reference 1, and FIG. 10B is a cross-sectional view of the poly-silicon resistor in accordance with Embodiment 1 described in Patent Reference 1;

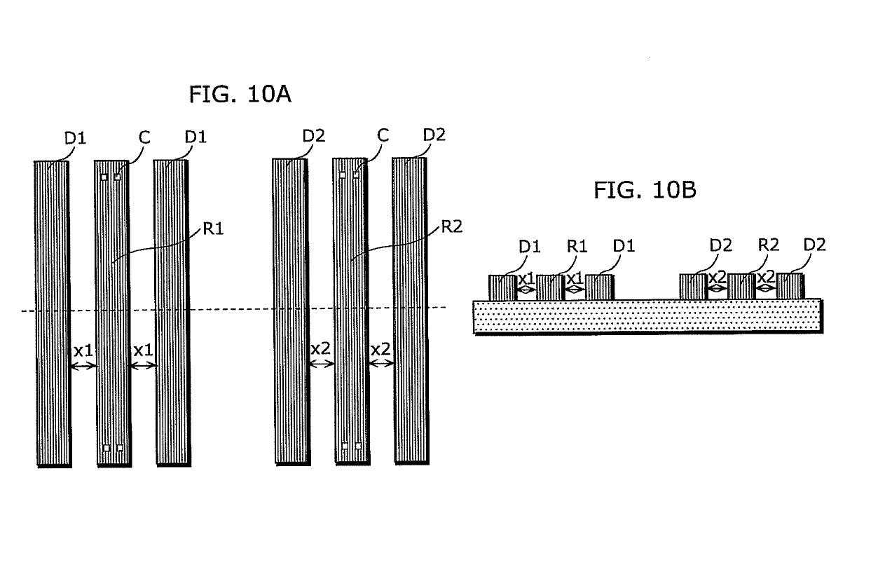

FIG. 11A is a plan view of the poly-silicon resistor in accordance with Embodiment 2 described in Patent Reference 1, and FIG. 11B is a cross-sectional view of the poly-silicon resistor in accordance with Embodiment 2 described in Patent Reference 1;

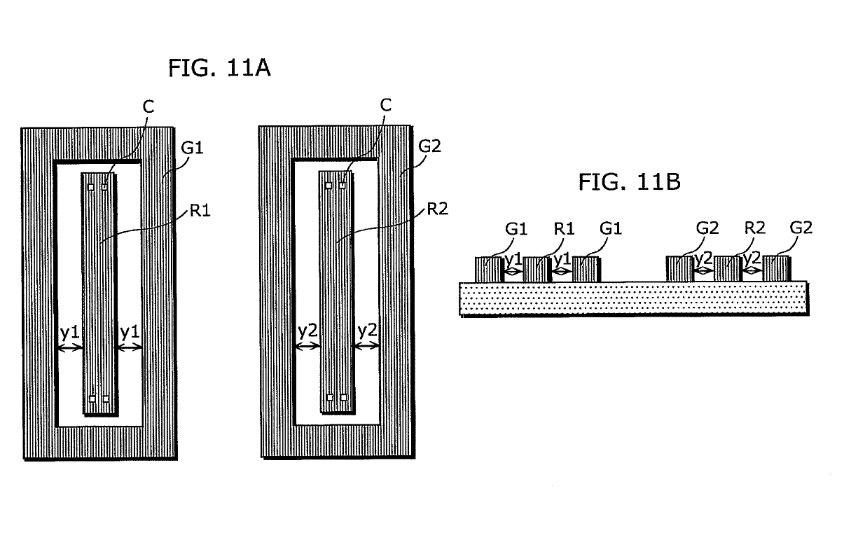

FIGS. 12A, 12B, and 12C are plan views of poly-silicon resistors in accordance with Embodiments 1, 2, and 3, respectively, described in Patent Reference 2;

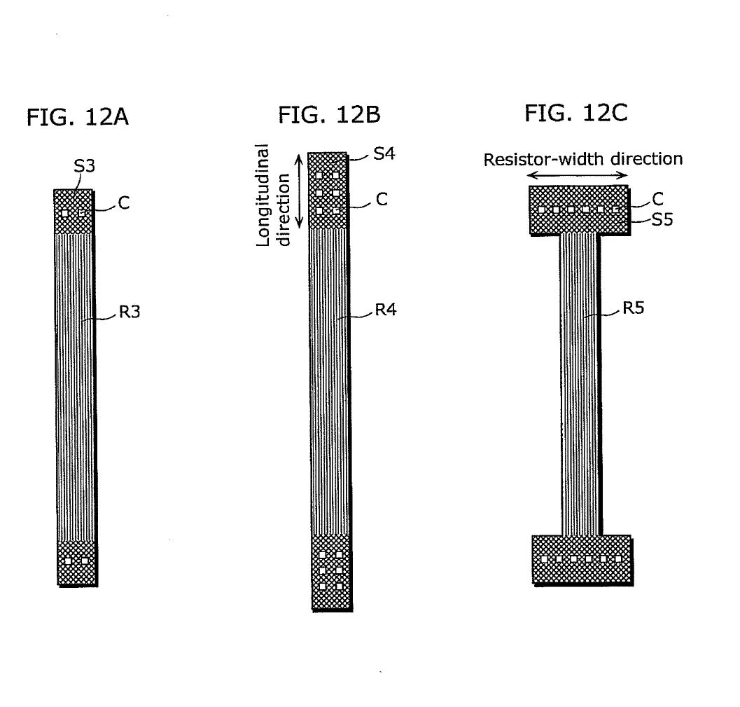

FIG. 13 is a graph illustrating resistance length dependency of a contact resistance contribution with respect to a resistance value of a resistor;

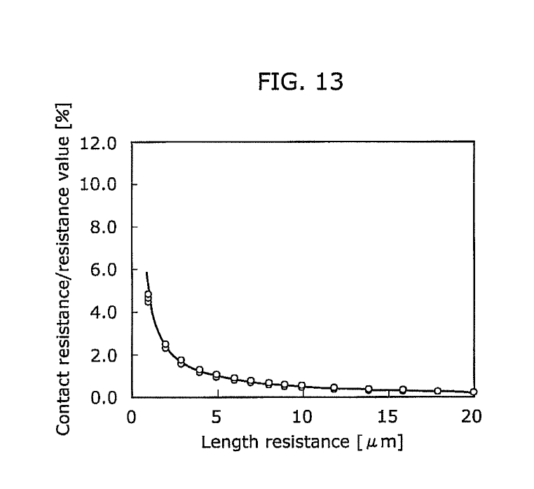

FIG. 14 is a graph illustrating the number of contacts dependency of a contact resistance contribution with respect to a resistance value of a resistor; and

FIG. 15A shows relationship between variations in resistance value of a resistor and the number of relative contacts, and FIG. 15B shows relationship between a mismatch of a resistor and the number of relative contacts.

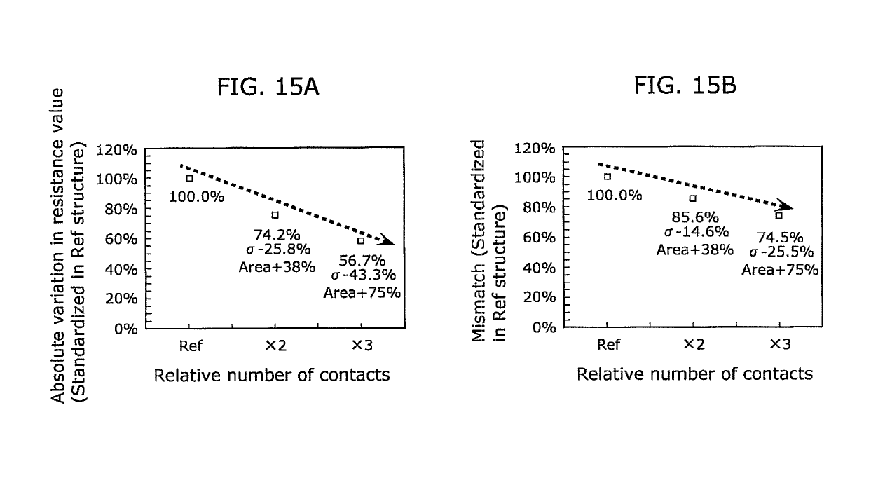

### DESCRIPTION OF THE PREFERRED EMBODIMENTS

### Embodiment 1

A semiconductor device according to Embodiment 1 includes: a semiconductor substrate; a resistor which is linearly formed above the semiconductor substrate, and made mainly of silicon; contact forming areas each of which (i) is formed in contact with one end of the resistor, and (ii) has a surface made of metal silicide; an interlayer insulating film formed on the resistor and the contact forming areas; and contact plugs each of which penetrates the interlayer insulating film and electrically connects an associated one of the contact forming areas to a metal wire formed on the interlayer insulating film, wherein an in-plane pattern of each of the contact forming areas is bent at least twice in a planar direction with respect to a linear direction of the resistor, so that a part of the contact forming area is formed in parallel with the resistor. The above structure makes possible equalizing local pattern densities near the patterns of the resistor. Thus, the structure can: equally provide the micro-loading effect to each pattern; and reduce variations in resistance value in order to reduce contact-plug-related resistance without enlarging a resistor size.

Described hereinafter in detail are a semiconductor device in accordance with Embodiment 1 and a manufacturing method thereof, with reference to the drawings.

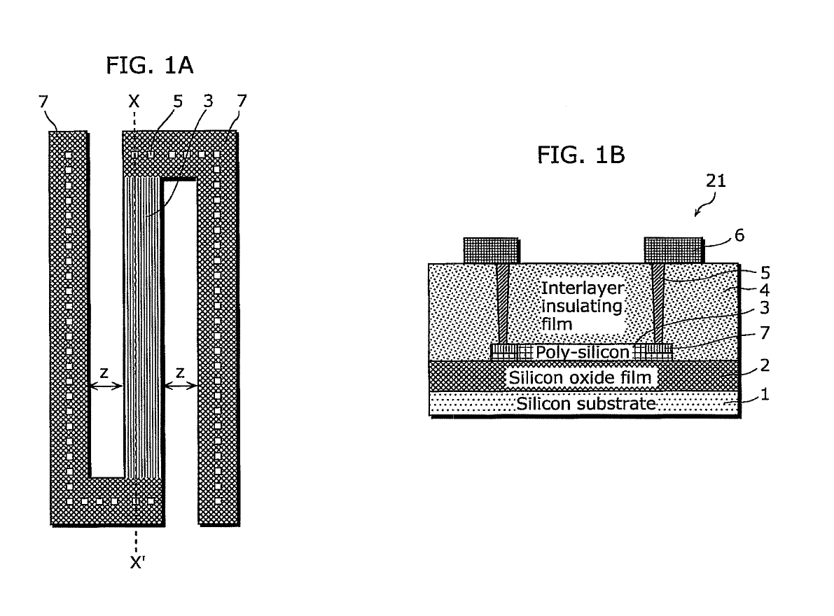

FIG. 1B is a cross-sectional view of the semiconductor device in accordance with Embodiment 1 of the present invention. A semiconductor device 21 illustrated in FIG. 1B includes a silicon substrate 1, a silicon oxide film 2, a resistor 3, an interlayer insulating film 4, a contact plug 5, a metal wire 6, and a contact forming area 7.

The silicon oxide film 2 is formed on the silicon substrate 1 in order to separate the substrate.

Mainly made of silicon, the resistor 3 is formed on the silicon oxide film 2. The resistor 3 is made of poly-silicon, for example.

The interlayer insulating film 4 is formed so as to cover the resistor 3 and the silicon oxide film 2.

The contact forming area 7, of which surface is made of metal-silicide, is formed at both ends of the resistor 3.

Formed in the interlayer insulating film 4 is a contact hole used for electrically connecting the contact forming area 7 and the metal wire 6. The contact hole is filled with the contact plug 5.

FIG. 1A is a plan view of a resistor and a contact forming area both included in the semiconductor device in accordance with Embodiment 1 of the present invention. As shown in FIG. 1A, the resistor 3 is linearly patterned in the plane. It is noted that FIG. 1B is a cross-sectional view of the semiconductor device 21 taken along line X-X′ of FIG. 1A.

At the both ends of the resistor 3, the respective contact forming areas 7 are connected. The in-plane pattern of each contact forming area 7 is bent twice in a stacking planar direction with respect to a linear direction of the resistor 3. Here, each contact forming area is connected to one end of the resistor 3. In other words, the in-plane pattern of the contact forming area 7 is bent twice in a planar direction with respect to a linear direction of the resistor 3. Accordingly, a part of the contact forming area 7 is formed in parallel with the resistor 3. Moreover, the part of the contact forming area 7 formed in parallel with the resistor 3 extends near the other end of the resistor 3. In other words, the resistor 3 is surrounded in the plane by two contact forming areas 7 including the contact forming area 7, except a space lying between the two contact forming areas 7.

In addition, the resistor 3, the two contact forming areas 7, and contact plugs 5 including the contact plug 5 are symmetrically arranged in the plane as viewed from the center in the plane of the resistor 3.

Moreover, each lying between the resistor 3 and the part of the contact forming area 7 which is in parallel with the resistor 3, distances “z” are equal. The value of the distance “z” follows the minimum rule which defines the design-wise allowable minimum value of the distance between the patterns.

Furthermore, each of the two contact forming areas 7 has the largest possible number of contact plugs 5 equally arranged.

The above structure can equalize local pattern densities near the patterns of the resistor 3. This equalized pattern densities can (i) equally provide the micro-loading effect to each pattern, and (ii) reduce variations in resistance value in order to reduce contact-plug-related resistance without enlarging a resistor size. In addition, the above structure makes possible minimizing the distance between the resistor and the contact forming area, which can realize a smaller chip size.

Furthermore, the above structure can (i) uniform resistance which is caused by each of the contact plugs 5 at the both ends of each resistor 3, and (ii) minimize variations in resistance value without enlarging the resistor size. This structure allows an analogue circuit to be implemented with the designing reflected to have high accuracy.

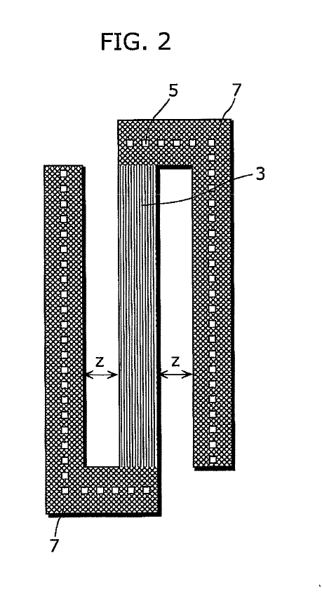

FIG. 2 is a plan view, of a resistor and a contact forming area, illustrating a modification in accordance with Embodiment 1 of the present invention. Comparison shows that the modification is different from the semiconductor device 21 in accordance with Embodiment 1 only in shapes of the in-plane patterns of the two contact forming areas 7. Described hereinafter are the differences in the shape of the in-plane pattern of the contact forming area 7 in accordance with Embodiment 1.

A part of the contact forming area 7, which lies in parallel with the resistor 3, extends to a connection part provided between the resistor 3 and the contact forming area 7.

In this structure, as well, the resistor 3 is surrounded in the plane by two contact forming areas 7 including the contact forming area 7, except a space lying between the two contact forming areas 7.

Thus, the semiconductor device in the modification achieves an effect similar to that of the semiconductor device in accordance with Embodiment 1.

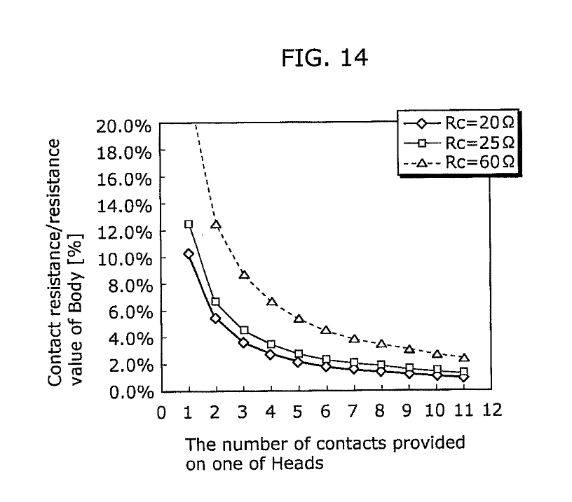

The contact forming area 7 is preferably large enough to have at least 10 contact plugs or more. This satisfactorily large contact forming area can reduce variations in resistance value caused by (i) variations in processing accuracy, and (ii) an increase in contact resistance value. FIG. 14 illustrates a graph showing the number of contacts dependency of a contact resistance contribution with respect to a resistance value of a resistor. When the contact resistance Rc is 60Ω a piece, the contact forming area can reduce the contribution rate of the contact resistance to 5% or below where the resistance value of the resistor 3 is 250Ω.

Described below is a manufacturing method of the semiconductor device 21 in accordance with Embodiment 1, using the drawings.

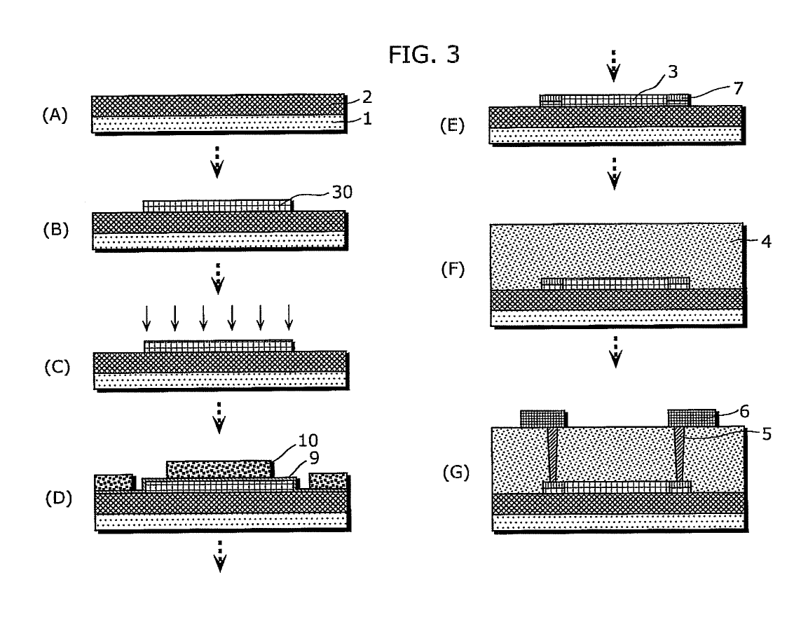

FIG. 3 is a cross-sectional flow sheet illustrating a manufacturing method of the semiconductor device in accordance with Embodiment 1 of the present invention.

As shown in FIG. 3 (A), the silicon oxide film 2 is formed on the surface of silicon substrate 1 by either the Local Oxidation of Silicon (LOCOS) growth, or the Shallow Trench Isolation (STI) trench formation.

Next, as shown in FIG. 3 (B), a poly-silicon film is laid on the surface of the silicon oxide film 2, and then patterned to be formed in a resistive region 30. Here, the resistive region 30 includes a first resistive region, two or more second resistive regions, and two or more third resistive regions. The first resistive region is linearly formed and provided in the plane. Each of the second resistive regions, which is linearly formed, makes contact with the first resistive region, and is bent at least twice in a planar direction with respect to a linear direction of the first resistive region. Each of the third resistive regions, which is linearly formed, makes contact with one end of the second resistive region, and lies in parallel with the first resistive region. Here, the one end does not make contact with the first resistive region.

Then, as shown in FIG. 3 (C), either B⁺ or As⁺, which is to be an ion species, is implanted into a surface of the resistive region 30 by the ion implantation technique, and is activated by heat treatment.

Next, as shown in FIG. 3 (D), a silicon oxide film 9 is formed on the entire surface, including the surface of the resistive region 30, of the silicon substrate 1. Then, photoresist is applied to the silicon oxide film 9, and a photoresist mask 10 is formed by the photolithography technique. Here, the photoresist mask 10 is formed on a part other than a part, of the resistive region 30, to be modified as the contact forming area 7. In other words, the photoresist mask 10 is not formed on a prospective area which is to correspond to a contact hole when the contact is formed. Next, the silicon oxide film 9 is selectively removed either by the wet etching technique or the dry etching, so that left is only the silicon oxide film 9 provided under the photoresist mask 10. This etching process exposes a prospective area for forming a contact out of the resistive region 30, the prospective area which is to be the contact forming area 7.

Then, as shown in FIG. 3 (E), silicide is formed. Specifically, titanium is applied to the entire surface, including the surface of the resistive region 30, of the silicon substrate 1. Then, heat treatment is provided to form the silicide, unreacted titanium is selectively removed, and heat treatment is provided to lower resistance. Here, a heat treatment is provided for forming silicide under the following condition, for example: 600 to 700° C. for several tens seconds to several minutes in either N₂ or Ar atmosphere using the ramp annealing technique. The selective removal of unreacted titanium involves etching using a compound liquid of which NH₄OH—H₂O₂—H₂ ratio is 1:1:4 (or a compound liquid including H₂SO₄, H₂O₂, H₂O). A heat treatment condition is provided for lowering resistance under the following condition: 800 to 900° C. within one minute in either N₂ or Ar atmosphere by a ramp annealing device. The above process forms the contact forming area 7, including titan silicide, in an area provided on a surface of the resistive region 30. Here, the provided area is used for connecting the contact plug 5.

In the resistive region 30, an area found between the contact forming areas 7 is defined as a resistor 3.

Next, as shown in FIG. 3 (F), the interlayer insulating film 4 is formed on the silicon substrate 1, and the contact hole is formed in the interlayer insulating film 4. Then, tungsten is filled in the contact hole, the Chemical Mechanical Polishing (CMP) is employed to planarize the surface of the interlayer insulating film 4, and the contact plug 5 is formed in the contact hole.

Finally, as shown in FIG. 3 (G), the metal wire 6 is formed on the surface of the interlayer insulating film 4 in contact with the contact plug 5. Here, the metal wire 6 is made of either aluminum or copper.

The semiconductor device 21 is formed via the above manufacturing process.

It is noted that the semiconductor device in accordance with Embodiment 1 and the manufacturing method thereof exemplify the use of titan silicide for forming the contact forming area 7; concurrently, another silicide including a refractory metal, such as cobalt silicide and nickel silicide, may also be used.

### Embodiment 2

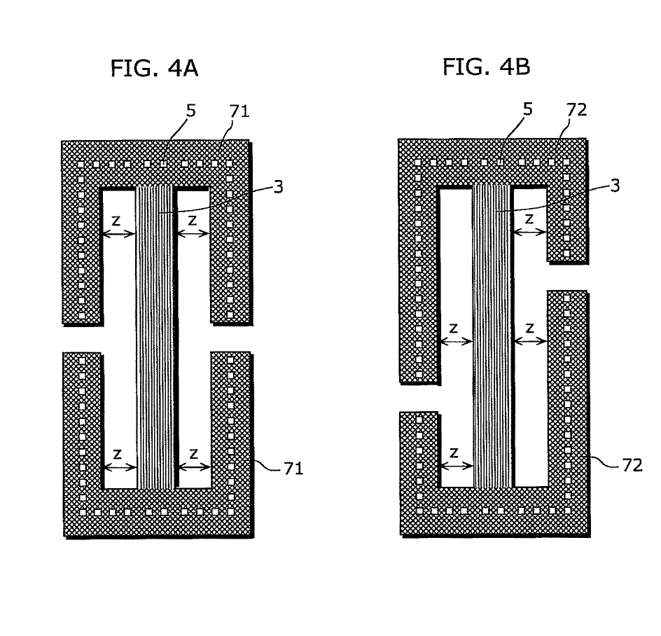

FIGS. 4A and 4B are plan views of a resistor and a contact forming area both included in a semiconductor device in accordance with Embodiment 2 of the present invention. Comparison shows that the semiconductor device in accordance with Embodiment 2 is different from the semiconductor device in accordance with Embodiment 1 only in in-plane pattern shape of the two contact forming areas 7. Described hereinafter are only the differences from Embodiment 1, and thus the points sharing with Embodiment 1 shall be omitted.

In plane patterns of the resistor and the contact forming area illustrated in FIG. 4A, a contact forming area 71 is formed at each end of the resistor 3. The in-plane pattern of each contact forming area 71 is bent at least twice in a staking planar direction with respect to the forming direction of the resistor 3. Here, the contact forming area 71 is connected to one end of the resistor 3. Accordingly, parts of the contact forming area 71 are formed lying in parallel with, on both sides of, the resistor 3.

In this structure, as well, the resistor 3 is surrounded in the plane by two contact forming areas 71 including the contact forming area 71, except spaces lying between the two contact forming areas 71.

In addition, the resistor 3, the two contact forming areas 71, and the contact plugs 5 are arranged to be symmetrical in a vertical line direction when viewed from the center in the plane of the resistor 3. Lying in parallel with the resistor 3 and formed on the both sides of the resistor 3, the parts of the contact forming area 71 are the same in length.

Moreover, each lying between the resistor 3 and the parts of the contact forming area 71 which are in parallel with the resistor 3, distances “z” are equal. The value of the distance “z” follows the minimum rule which defines the minimum value of the distance between the patterns which are design-wise allowable.

Furthermore, each of the two contact forming areas 71 has the largest possible number of contact plugs 5 equally arranged.

The above structure makes possible equalizing local pattern densities near the patterns of the resistor 3. Thus, the structure can: equally provide the micro-loading effect to each pattern; and reduce variations in resistance value in order to reduce contact-plug-related resistance without enlarging a resistor size. In addition, the above structure makes possible minimizing the distance between the resistor and the contact forming area, which can realize a smaller chip size.

Furthermore, the above structure can (i) uniform resistance which is caused by each of the contact plugs 5 at the both ends of each resistor 3, and (ii) minimize variations in resistance value without enlarging the resistor size. Thus, the structure can implement an analogue circuit having high accuracy, reflecting the designing.

It is noted that the space between the two contact forming area 71 does not necessarily lies in the center of the resistor 3.

Comparison shows that the plane patterns of the resistor and of the contact forming area illustrated in FIG. 4B are different from those illustrated in FIG. 4A only in in-plane pattern shape of two contact forming areas 72. Described hereinafter are only the differences from the in-plane pattern shape of the contact forming area 71 illustrated in FIG. 4A.

The in-plane pattern of each contact forming area 72 is bent at least twice in a staking planar direction with respect to the forming direction of the resistor 3. Here, the contact forming area 72 is connected to one end of the resistor 3. Accordingly, parts of the contact forming area 72 are formed lying in parallel with, on both sides of, the resistor 3.

In addition, the resistor 3, the two contact forming areas 72, and the contact plugs 5 are point-symmetrically arranged in the plane as viewed from the center in the plane of the resistor 3. Lying in parallel with the resistor 3 and formed on the both sides of the resistor 3, the parts of the contact forming area 72 are different in length.

Thus, having the resistor and the contact forming area both illustrated in FIG. 4B, the semiconductor device achieves an effect similar to that of the semiconductor device having the resistor and the contact forming area both illustrated in FIG. 4A.

### Embodiment 3

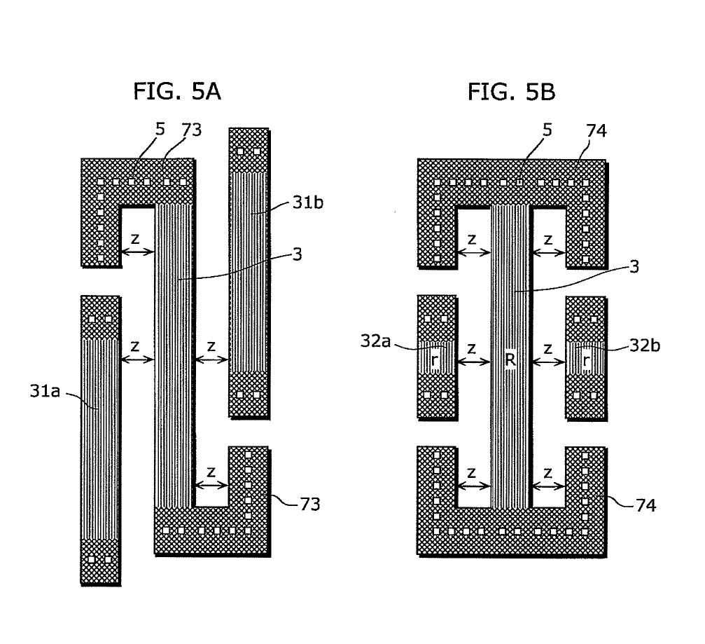

FIGS. 5A and 5B are plan views of a resistor and a contact forming area both included in a semiconductor device in accordance with Embodiment 3 of the present invention. Comparison shows that the semiconductor device in accordance with Embodiment 3 is different from the semiconductor device in accordance with Embodiment 1 only in the point where the resistor 3 is surrounded by a contact forming area and a resistor lies adjacent to the resistor 3. Described hereinafter are only the differences from Embodiment 1, and thus the points sharing with Embodiment 1 shall be omitted.

In the resistor and the contact forming area illustrated in FIG. 5A, a contact forming area 73 is formed at each end of the resistor 3. The in-plane pattern of each contact forming area 73 is bent twice in a stacking planar direction with respect to a linear direction of the resistor 3. Here, the contact forming area 73 is connected to one end of the resistor 3. Accordingly, a part of the contact forming area 73 is formed in parallel with the resistor 73.

Furthermore, other resistors 31a and 31b lie adjacent to the resistor 3 and the contact forming area 73. In the plane, the resistor 3 is surrounded by two contact forming areas 73 including the contact forming area 73 and the resistors 31a and 31b except spaces lying between two among from the contact forming areas 73, and the resistors 31a and 31b.

In addition, the resistor 3, the two contact forming areas 73, and the contact plugs 5, and the resistors 31a and 31b are symmetrically arranged in the plane as viewed from the center in the plane of the resistor 3.

Moreover, each lying (i) between the resistor 3 and the part of the contact forming area 73 which is in parallel with the resistor 3, and (ii) between the resistor 3 and the resistors 31a and 31b, the distances “z” are equal. The value of the distance “z” follows the minimum rule which defines the minimum value of the distance between the patterns which are design-wise allowable.

Furthermore, each of the two contact forming areas 73 has the largest possible number of contact plugs 5 equally arranged.

This structure makes possible equalizing local pattern densities near the patterns of the resistor 3. Thus, the structure can: equally provide the micro-loading effect to each pattern; and reduce variations in resistance value in order to reduce contact-plug-related resistance without enlarging a resistor size. In addition, the above structure makes possible minimizing the distance between the resistor and the contact forming area, which can realize a smaller chip size.

Furthermore, the above structure can (i) uniform resistance which is caused by each of the contact plugs 5 at the both ends of each resistor 3, and (ii) minimize variations in resistance value without enlarging the resistor size. Thus, the structure can implement an analogue circuit having high accuracy, reflecting the designing.

Comparison shows that the plane patterns of the resistor and the contact forming area illustrated in FIG. 5B are different from those illustrated in FIG. 5A in in-plane pattern shape of (i) two contact forming areas, and (ii) another resistor lying adjacent to the two contact forming area. Described hereinafter are only the differences from the in-plane pattern shape of the contact forming area 73 illustrated in FIG. 5A.

In plane patterns of the resistor and the contact forming area illustrated in FIG. 5B, a contact forming area 74 is formed at each end of the resistor 3. The in-plane pattern of each contact forming area 74 is bent twice in a stacking planar direction with respect to a linear direction of the resistor 3. Here, the contact forming area 74 is connected to one end of the resistor 3. Accordingly, parts of the contact forming area 74 are formed lying in parallel with, on both sides of, the resistor 3.

Furthermore, other resistors 32a and 32b lie adjacent to the resistor 3 and the contact forming area 74. The resistors 32a and 32b are placed between the respective two contact forming areas 74 including the contact forming area 74. In the plane, the resistor 3 is surrounded by two contact forming areas 74 including the contact forming area 74 and the resistors 32a and 32b except spaces lying between two among from the contact forming areas 74, and the resistors 32a and 32b.

Thus, having the resistor and the contact forming area both illustrated in FIG. 5B, the semiconductor device achieves an effect similar to that of the semiconductor device having the resistor and the contact forming area both illustrated in FIG. 5A.

### Embodiment 4

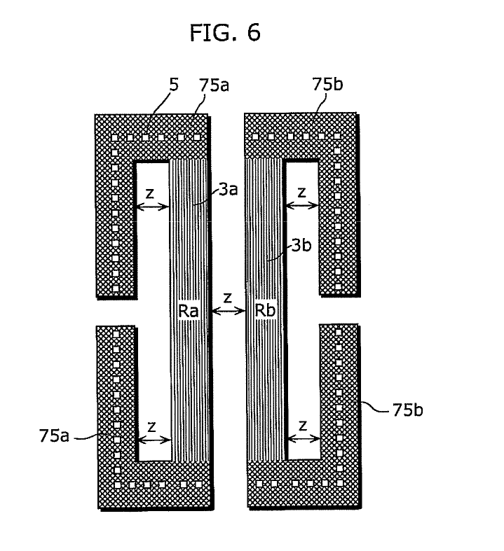

FIG. 6 is a plan view of a resistor and a contact forming area both included in the semiconductor device in accordance with Embodiment 4 of the present invention. As shown in FIG. 6, resistors 3a and 3b are poly-silicon resistors provided in a pair. The resistors 3a and 3b are each linearly patterned in the plane.

At each end of the resistor 3a, contact forming area 75a is connected. With respect to the forming direction of the resistor 3a, the in-plane pattern of the contact forming area 75a is bent twice in a planar direction opposite the resistor 3b. Here, the contact forming area 75a is connected to one end of the resistor 3a. Thus, parts of the contact forming area 75a are formed lying in parallel with the resistor 3a. In other words, the resistor 3a is surrounded in the plane by two contact forming areas 75a including the contact forming area 75a, except a space lying between the two contact forming areas 75a.

At each end of the resistor 3b, the contact forming area 75b is connected. With respect to the forming direction of the resistor 3b, the in-plane pattern of the contact forming area 75b is bent twice in a planar direction opposite the resistor 3a. Here, the contact forming area 75b is connected to one end of the resistor 3b. Thus, parts of the contact forming area 75b are formed lying in parallel with the resistor 3b. In other words, the resistor 3b is surrounded in the plane by two contact forming areas 75b including the contact forming area 75b, except a space lying between the two contact forming areas 75b.

In addition, the resistors 3a and 3b, the contact forming areas 75a and 75b, and the contact plugs 5 are symmetrically arranged in the plane as viewed from the center in the plane of the resistors 3a and 3b.

Moreover, each lying (i) between the resistors 3a and 3b, (ii) between the resistor 3a and the part of the contact forming area 75a which is in parallel with the resistors 3a, and (iii) between the resistor 3b and the part of the contact forming area 75b which is in parallel with the resistors 3b, the distances “z” are equal. The value of the distance “z” follows the minimum rule which defines the minimum value of the distance between the patterns which are design-wise allowable.

Furthermore, each of the contact forming areas 75a and 75b has the largest possible number of contact plugs 5 equally arranged.

This structure makes possible equalizing local pattern densities near the patterns of the resistors 3a and 3b. Thus, the structure can: equally provide the micro-loading effect to each pattern; and reduce variations in resistance value in order to reduce contact-plug-related resistance without enlarging a resistor size. In addition, the above structure makes possible minimizing the distance between the resistor and the contact forming area, which can realize a smaller chip size.

Furthermore, the above structure can (i) uniform resistance which is caused by each of the contact plugs 5 at the both ends of each of the resistors 3a and 3b, and (ii) minimize variations in resistance value without enlarging the resistor size. This can implement an analogue circuit having high accuracy, reflecting the designing.

### Embodiment 5

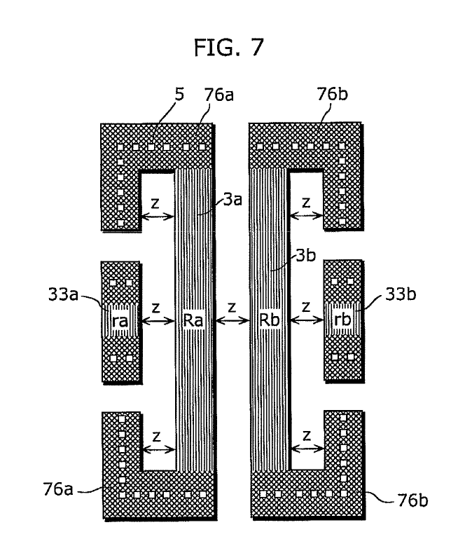

FIG. 7 is a plan view of a resistor and a contact forming area both included in the semiconductor device in accordance with Embodiment 5 of the present invention. As shown in FIG. 7, the resistors 3a and 3b are: poly-silicon resistors provided in a pair; and each linearly patterned in the plane.

At each end of the resistor 3a, a contact forming area 76a is connected. With respect to the forming direction of the resistor 3a, the in-plane pattern of the contact forming area 76a is bent twice in a planar direction opposite the resistor 3b. Here, the contact forming area 76a is connected to one end of the resistor 3a. Thus, parts of the contact forming area 76a are formed lying in parallel with the resistor 3a.

At each end of the resistor 3b, the contact forming area 76b is connected. With respect to the forming direction of the resistor 3b, the in-plane pattern of the contact forming area 76b is bent twice in a planar direction opposite the resistor 3a. Here, the contact forming area 76b is connected to one end of the resistor 3b. Thus, parts of the contact forming area 76b are formed lying in parallel with the resistor 3b.

Furthermore, another resistor 33a lies adjacent to the resistor 3a and the contact forming area 76a. The resistor 33a is placed between two contact forming areas 76a including the contact forming area 76a.

Furthermore, another resistor 33b lies adjacent to the resistor 3b and the contact forming area 76b. The resistor 33b is placed between two contact forming areas 76b including the contact forming area 76b.

The resistors 3a and 3b are surrounded in the plane by the contact forming areas 76a and 76b and the resistors 33a and 33b, except spaces lying between two among from the contact forming areas 76a and 76b, and the resistors 33a and 33b.

In addition, the resistors 3a and 3b, the contact forming areas 76a and 76b, and the contact plugs 5 are symmetrically arranged in the plane as viewed from the center in the plane of the resistors 3a and 3b.

Moreover, each lying (i) between the resistors 3a and 3b, (ii) between the resistor 3a and the part of the contact forming area 76a which is in parallel with the resistors 3a, (iii) between the resistors 3a and 33b, (IV) between the resistor 3b and the part of the contact forming area 76b which is in parallel with the resistors 3b, and (V) between the resistors 3b and 33b, the distances “z” are equal. The value of the distance “z” follows the minimum rule which defines the minimum value of the distance between the patterns which are design-wise allowable.

Furthermore, each of the contact forming areas 76a and 76b has the largest possible number of contact plugs 5 equally arranged.

This structure makes possible equalizing local pattern densities near the patterns of the resistors 3a and 3b. Thus, the implementation of the present invention can: equally provide the micro-loading effect to each pattern; and reduce variations in resistance value in order to reduce contact-plug-related resistance without enlarging a resistor size. In addition, the above structure makes possible minimizing the distance between the resistor and the contact forming area, which can realize a smaller chip size.

Furthermore, the above structure can (i) uniform resistance which is caused by each of the contact plugs 5 at the both ends of each of the resistors 3a and 3b, and (ii) minimize variations in resistance value without enlarging the resistor size. This can implement an analogue circuit having high accuracy, reflecting the designing.

### Embodiment 6

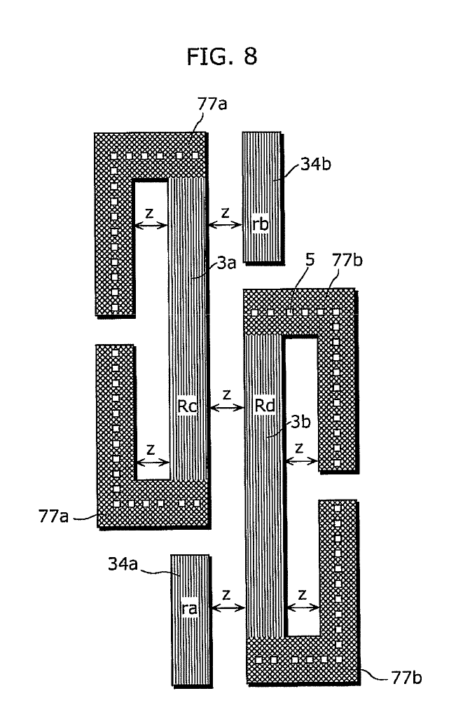

FIG. 8 is a plan view of a resistor and a contact forming area both included in the semiconductor device in accordance with Embodiment 6 of the present invention. As shown in FIG. 8, the resistors 3a and 3b are poly-silicon resistors provided in a pair; and each linearly patterned in the plane.

Comparison shows that the resistors 3a and 3b are different from the pairs of the resistors shown in FIGS. 6 and 7 in the point where one of the resistors is shifted in a longitudinal direction of the resistors.

At each end of the resistor 3a, a contact forming area 77a is connected. With respect to the forming direction of the resistor 3a, the in-plane pattern of the contact forming area 77a is bent twice in a planar direction opposite the resistor 3b. Here, the contact forming area 77a is connected to one end of the resistor 3a. Thus, parts of the contact forming area 77a are formed lying in parallel with the resistor 3a.

At each end of the resistor 3b, the contact forming area 77b is connected. With respect to the forming direction of the resistor 3b, the in-plane pattern of the contact forming area 77b is bent twice in a planar direction opposite the resistor 3a. Here, the contact forming area 77b is connected to one end of the resistor 3b. Thus, parts of the contact forming area 77b are formed lying in parallel with the resistor 3b.

Furthermore, another resistor 34b lies adjacent to the resistor 3a and the contact forming area 77a.

In addition, another resistor 34a lies adjacent to the resistor 3b and the contact forming area 77b.

The resistors 3a and 3b are surrounded in the plane by the contact forming areas 77a and 77b and the resistors 34a and 34b, except spaces lying between two among from the contact forming areas 77a and 77b, and the resistors 34a and 34b.

In other words, the resistors 3a and 3b are surrounded by either a contact forming area of the resistors 3a and 3b, or a neighboring resistor.

In addition, the resistors 3a and 3b, the contact forming areas 77a and 77b, and the contact plugs 5 are point-symmetrically arranged in the plane as viewed from the center in the plane of the resistors 3a and 3b.

Moreover, each lying (i) between the resistors 3a and 3b, (ii) between the resistor 3a and the part of the contact forming area 77a which is in parallel with the resistors 3a, (iii) between the resistors 3a and 34b, (IV) between the resistor 3b and the part of the contact forming area 77b which is in parallel with the resistors 3b, and (V) between the resistors 3b and 34a, the distances “z” are equal. The value of the distance “z” follows the minimum rule which defines the minimum value of the distance between the patterns which are design-wise allowable.

Furthermore, each of the contact forming areas 77a and 77b has the largest possible number of contact plugs 5 equally arranged.

This structure makes possible equalizing local pattern densities near the patterns of the resistors 3a and 3b. Thus, the structure can: equally provide the micro-loading effect to each pattern; and reduce variations in resistance value in order to reduce contact-plug-related resistance without enlarging a resistor size. In addition, the above structure makes possible minimizing the distance between the resistor and the contact forming area, which can realize a smaller chip size.

Furthermore, the above structure can (i) uniform resistance which is caused by each of the contact plugs 5 at the both ends of each of the resistors 3a and 3b, and (ii) minimize variations in resistance value without enlarging the resistor size. This can implement an analogue circuit having high accuracy, reflecting the designing.

As described above, a semiconductor device and a manufacturing method thereof according to an implementation of the present invention can reduce, without enlarging the resistor size, (i) variations in resistance value caused by an increasing proportion of a contact resistance value, and (ii) variations in resistance value due to the micro-loading effect even though a resistor included in an analogue circuit becomes smaller and the length resistance is reduced. Thus, the implementation can achieve both of reducing a chip size and improving accuracy of an analogue circuit.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

Embodiments 1 to 6 exemplify that the in-plane bending is referred to as the case of the in-plane pattern of the contact forming area bending 90 degrees to an in-plane direction with respect to a linear direction of the resistor; concurrently, the bending angle of the in-plane bending may be other than 90 degrees. Furthermore, the bending part may be rounded in consideration of pattern workability and optimality of circuit designing of a contact forming area.

Embodiments 1 to 6 further exemplify a resistor formed in a straight line; simultaneously, a resistor is not limited to be formed in a straight line as far as two contact forming areas, used for running a current to the resistor, can make contact with the resistor.

### INDUSTRIAL APPLICABILITY

A semiconductor device and a manufacturing method thereof according to an implementation of the present invention are especially effective for a semiconductor device including an analogue circuit employing a poly-silicon resistor and a manufacturing method thereof.

What is claimed is:

1. A semiconductor device included in an analogue circuit, said semiconductor device comprising:
a semiconductor substrate;
a resistor which is linearly formed above said semiconductor substrate, and made mainly of silicon;
contact forming areas each of which (i) is formed in contact with one end of said resistor, and (ii) has a surface made of metal silicide;
an interlayer insulating film formed on said resistor and said contact forming areas; and
contact plugs each of which penetrates said interlayer insulating film and electrically connects an associated one of said contact forming areas to a metal wire formed on said interlayer insulating film,
wherein an in-plane pattern of each of said contact forming areas is bent at least twice in a planar direction with respect to a linear direction of said resistor, so that a part of said contact forming area is formed in parallel with said resistor.

2. The semiconductor device according to claim 1,
wherein said resistor is surrounded by said contact forming areas in a plane except a space lying between said contact forming areas.

3. The semiconductor device according to claim 1,
wherein said resistor is surrounded in the plane by said contact forming areas and said resistor adjacent to said contact forming areas except a space lying between two from among said contact forming areas and the resistor adjacent to said resistor.

4. The semiconductor device according to claim 1,
wherein said resistor, said contact forming areas and said contact plugs formed on said contact forming areas are symmetrically arranged in the plane as viewed from center in the plane of said resistor.

5. The semiconductor device according to claim 1,
wherein a gap between said resistor and the part of said contact forming area is a smallest allowable value for inter-pattern distance, said contact forming area being formed in parallel with said resistor.

6. The semiconductor device according to claim 1, wherein each of said contact forming areas has a largest possible number of the contact plugs equally arranged.

7. A method for manufacturing a semiconductor device included in an analogue circuit, said method comprising:
stacking a resistance layer, mainly made of silicon, on a semiconductor substrate;
patterning the resistance layer to form a resistive region including a first resistive region, two or more second resistive regions, and two or more third resistive regions, (i) the first resistive region being linearly formed, (ii) the two or more second resistive regions each being linearly formed, making contact with the first resistive region, and bent at least twice in a planar direction out of the first resistive region, and (iii) the two or more third resistive regions each being linearly formed, making contact with one end, of the second resistive region, which does not contact with the first resistive region, and lying in parallel with the first resistive region;
metal-siliciding a surface of the second resistive region and a surface of the third resistive region in order to make the second resistive region and the third resistive region into a contact forming area;
forming an interlayer insulating film on the first resistive region and the contact forming area; and
forming contact plugs each of which penetrates the interlayer insulating film and electrically connects an associated one of the contact forming areas to a metal wire formed on the interlayer insulating film.
